(19) United States
(12) Patent Application Publication
(10) Pub. No.: US 2024/0112829 A1
(43) Pub. Date: Apr. 4, 2024

(54) ELECTRICAL HARNESS COMPRISING AN ELECTROMAGNETIC PROTECTION SYSTEM AND A SYSTEM FOR DETECTING ELECTRIC ARCS, AND PROCESS FOR MANUFACTURING SUCH AN ELECTRICAL HARNESS

(71) Applicant: Airbus SAS, BLAGNAC (FR)

(72) Inventors: Christophe DESJEAN, BLAGNAC (FR); Didier CHASSAIGNE, BLAGNAC (FR); Frédéric FORGET, BLAGNAC (FR)

(21) Appl. No.: 18/479,267

(22) Filed: Oct. 2, 2023

(30) Foreign Application Priority Data
Oct. 4, 2022 (FR) 2210113

(51) Int. Cl. H01B 7/04; H01B 7/00

(52) U.S. Cl. CPC H01B 7/043; H01B 7/0018; H01B 7/0045

(57) ABSTRACT

An electrical harness comprising at least one electrical connection, an electromagnetic protection system, a system for detecting electric arcs, and a tubular jacket obtained by braiding bundles of strands comprising metal strands forming at least part of the electromagnetic protection system and strands in the form of segments of optical fiber forming at least part of the system for detecting electric arcs. This solution contributes to reducing the mass of an electrical harness.

### CROSS-REFERENCES TO RELATED APPLICATIONS

This application claims the benefit of the French patent application No. 2210113 filed on Oct. 4, 2022, the entire disclosures of which are incorporated herein by way of reference.

### FIELD OF THE INVENTION

The present application relates to an electrical harness comprising an electromagnetic protection system and a system for detecting electric arcs, and to a process for manufacturing such an electrical harness.

### BACKGROUND OF THE INVENTION

According to one embodiment that can be seen in FIG. 1, an electrical harness 10 comprises at least one electrical connection 12 comprising at least one conductive element, and an electromagnetic protection system 14 comprising a tubular jacket 16, surrounding the electrical connection 12, obtained by braiding bundles 16.1 of metal strands 16.2. According to one configuration, the tubular jacket 16 comprises sixteen bundles 16.1 each of five metal strands 16.2.

Document FR3101195 describes an electrical connection equipped with a system for detecting electric arcs. According to this document, the electrical connection comprises an electrical conductor surrounded by an insulating jacket. In addition, the system for detecting an electric arc comprises a textile web, composed of a plurality of optical fibers and transparent weft threads (which let light through), wound around the insulating jacket, a photo-detection component configured to receive a light beam guided by the optical fibers and to emit an electrical signal depending on the light beam received, and a control unit configured to control the circuit breaker depending on the electrical signal emitted by the photo-detection component. Thus, if an electric arc appears, the luminous flux generated by the latter is captured by the optical fibers which transmit it to the photo-detection component which generates an electrical signal which is sent to a circuit breaker.

Integrating an electromagnetic protection system and a system for detecting electric arcs in the same electrical harness is not optimal since it requires two coaxial tubular jackets, one for each system, this leading to a significant increase in the mass of the electrical harness.

The present invention seeks to overcome all or some of the drawbacks of the prior art.

### SUMMARY OF THE INVENTION

To this end, one subject of the invention is an electrical harness comprising:
at least one electrical connection,
an electromagnetic protection system comprising a tubular jacket obtained by braiding bundles of strands and positioned around the electrical connection, at least 80% of the strands of the bundles being made of metal,
a system for detecting electric arcs which comprises at least one optical fiber positioned close to the electrical connection and at least one photo-detection component configured to receive a light beam guided by the optical fiber.

According to the invention, the tubular jacket comprises strands in the form of segments of optical fiber forming at least part of the system for detecting electric arcs.

According to the invention, the strands in the form of segments of optical fiber have a diameter that is substantially identical to that of the metal strands.

According to the invention, the same tubular jacket comprises metal strands forming at least part of the electromagnetic protection system and strands in the form of segments of optical fiber forming at least part of the system for detecting electric arcs. This solution contributes to reducing the mass of an electrical harness integrating the functions of electromagnetic protection and electric-arc detection.

According to another feature, all the strands are made of metal for at least half of the bundles of the tubular jacket while at least 75% of the strands are made of metal for the other bundles of the tubular jacket.

According to one embodiment, the tubular jacket comprises sixteen bundles and four strands, each in the form of a segment of optical fiber, regularly distributed around the electrical connection in four bundles.

According to another embodiment, the tubular jacket comprises sixteen bundles and eight strands, each in the form of a segment of optical fiber, regularly distributed around the electrical connection in eight bundles.

According to another feature, each optical fiber is a single-mode or multi-

mode optical fiber.

According to another feature, the segments of optical fiber are connected in parallel.

According to another feature, each strand in the form of a segment of optical fiber extends over the entire length of the tubular jacket and has at least one excess length at at least one end of the tubular jacket.

Another subject of the invention is a process for manufacturing an electrical harness according to one of the preceding features. According to the invention, the tubular jacket is obtained by simultaneously overbraiding, on the electrical connection, metal strands forming at least part of the electromagnetic protection system and strands in the form of segments of optical fiber forming at least part of the system for detecting electric arcs.

Another subject of the invention is an aircraft comprising at least one electrical harness according to one of the preceding features.

### BRIEF DESCRIPTION OF THE DRAWINGS

Other features and advantages will become apparent from the following description of the invention, which description is given solely by way of example, with reference to the appended drawings in which:

FIG. 1 is a schematic representation of an electrical harness, illustrating one embodiment of the prior art,

FIG. 2 is a side view of an aircraft,

FIG. 3 is a side view of an electrical harness, illustrating one embodiment of the invention,

FIG. 4 is a schematic representation of an electrical harness, illustrating a first embodiment of the invention,

FIG. 5 is a cross section through the electrical harness that can be seen in FIG. 4, and

FIG. 6 is a cross section through an electrical harness, illustrating another embodiment of the invention.

### DETAILED DESCRIPTION OF THE PREFERRED EMBODIMENTS

According to one embodiment that can be seen in FIGS. 3 to 6, an electrical harness 20 comprises at least one electrical connection 22 comprising at least one conductive element, and an electromagnetic protection system 24 surrounding the electrical connection 22.

This electromagnetic protection system 24 makes it possible to obtain shielding, around the electrical connection 22, configured to protect said electrical connection from electromagnetic interference generated by external elements and to protect elements external to the electrical harness 20 from electromagnetic interference generated by the electrical connection 22.

The electrical connection 22 may comprise a plurality of conductive elements 22.1, as illustrated in FIGS. 5 and 6, each comprising an insulating jacket in the form of a plastic sheath, for example.

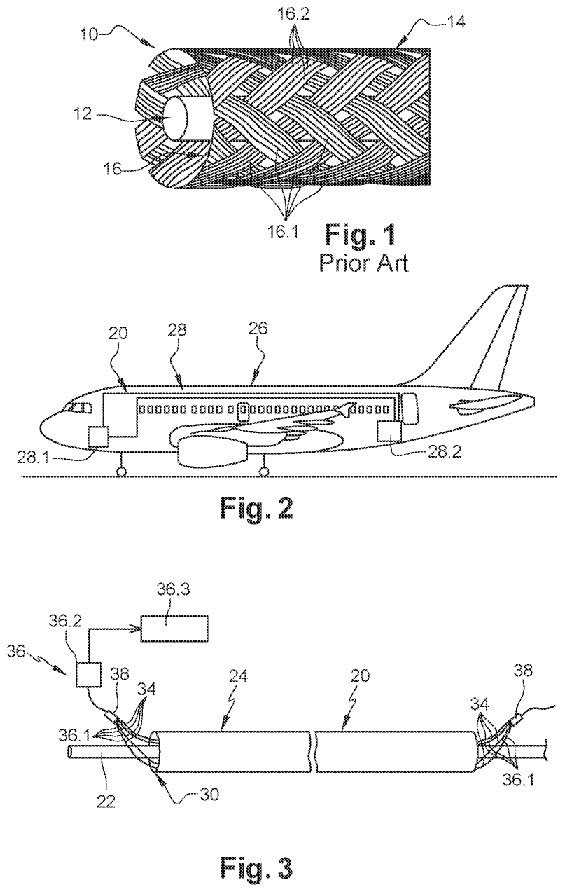

According to one application that can be seen in FIG. 2, an aircraft 26 comprises an electrical installation 28 comprising at least one high-voltage electric power source 28.1, at least one piece of user equipment 28.2, and at least one electrical harness 20 connecting the high-voltage electric power source 28.1 to the user equipment 28.2. According to one configuration, the high-voltage electric power source supplies a DC voltage of the order of + or −270 Volts DC, or else of + or −540 Volts DC. Of course, the invention is not limited to this application or to these voltages.

The electromagnetic protection system 24 comprises a tubular jacket 30 obtained by braiding and positioned around the electrical connection. This tubular jacket 30 comprises a plurality of bundles 30.1 each comprising a plurality of strands 32, 34. According to one embodiment, the tubular jacket 30 comprises sixteen bundles 30.1 each of five strands 32, 34. Of course, the invention is not limited to this number of bundles or strands for each bundle. Furthermore, the elementary diameter of each strand may vary within the same bundle or between two bundles. The majority of the strands 32 of the various bundles 30.1 are made of metal in order to obtain the electromagnetic protection system 24. According to one embodiment, the metal strands 32 are based on nickel-plated or tin-plated or silver-plated copper.

According to one configuration, the metal strands 32 have a diameter of the order of 150 to 250 μm.

Regardless of the configuration, in order to obtain the electromagnetic protection system 24, the metal strands 32 have to cover at least 85% of the surface area of the tubular jacket 30. Furthermore, at low frequency, the tubular jacket 30 has to have a linear resistance of the order of 5 mOhm/m and an inductance of the order of 2 nH.

In order to obtain these characteristics, at least 80% of the strands 32 of the bundles 30.1, 30.1′ of the tubular jacket 30 are made of metal. Preferably, at least 90% of the strands 32 are made of metal. According to one distribution, half or more of the bundles 30.1 are made exclusively from metal strands 32, the other bundles 30.1′ comprising at least 75% metal strands 32.

According to one arrangement, all the bundles 30.1 have the same number of strands 32, 34. Each bundle 30.1, 30.1′ is in the form of a web of strands 32, 34 juxtaposed next to each other. Thus, each bundle 30.1, 30.1′ comprises a first end strand 32, 34 and a second end strand 32, 34 spaced apart as far as possible from the first end strand.

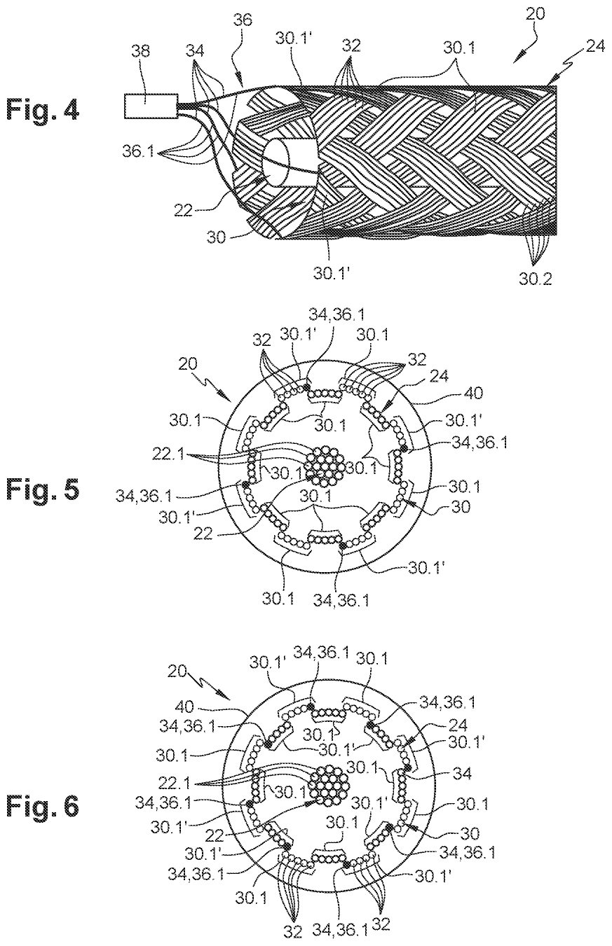

According to a first embodiment that can be seen in FIGS. 4 and 5, 75% of the bundles 30.1 are made exclusively from metal strands 32, the other bundles 30.1′ comprising at least 80% metal strands 32, that is to say, four metal strands 32 out of five strands.

According to a second embodiment that can be seen in FIG. 6, 50% of the bundles 30.1 are made exclusively from metal strands 32, the other bundles 30.1′ comprising at least 80% metal strands 32, that is to say, four metal strands 32 out of five strands.

According to one embodiment that can be seen in FIG. 3, the electrical harness 20 also comprises a system 36 for detecting electric arcs which comprises at least one optical fiber 36.1 positioned close to the electrical connection 22, at least one photo-detection component 36.2 configured to receive a light beam guided by the optical fiber 36.1 and to emit an electrical signal depending on the light beam received, and at least one control unit 36.3 configured to emit at least one control signal depending on the electrical signal emitted by the photo-detection component 36.2. More precisely, the at least one optical fiber 36.1 is positioned at least in part around the electrical connection 22.

According to one configuration, the system 36 for detecting electric arcs also comprises at least one circuit breaker positioned on the electrical connection 22, dividing it into upstream and downstream segments, configured to assume a closed state in which it allows the current to pass through the upstream and downstream segments of the electrical connection 22 and an open state in which it interrupts the flow of the current between the upstream and downstream segments of the electrical connection 22 in response to receiving a control signal transmitted by the control unit 36.3. The system 36 for detecting electric arcs is not limited to this electrical circuit breaker function. Thus, it is possible to ensure an optical locking function at the time of ignition (a function of making the electrical connection safe in the event of disconnection by a maintenance operator) or any other function.

Each optical fiber 36.1 comprises at least one segment forming a strand 34 of one of the bundles 30.1′ of the tubular jacket 30 of the electromagnetic protection system 24. According to one configuration, the same optical fiber 36.1 comprises a plurality of segments each forming a strand 34 of various bundles 30.1′. According to another configuration that can be seen in FIG. 4, each optical fiber 36.1 comprises a single segment forming one strand 34 of a bundle 30.1′.

According to these two configurations, all the non-metal strands 34 are segments of optical fiber 36.1. Thus, the strands 32, 34 of the bundles 30.1, 30.1′ of the tubular jacket 30 are exclusively made of metal or in the form of segments of optical fiber 36.1. Thus, according to the invention, the same tubular jacket 30 comprises metal strands 32 forming at least part of the electromagnetic protection system 24 and strands 34 in the form of segments of optical fiber 36.1 forming at least part of the system 36 for detecting electric arcs. This solution contributes to reducing the mass of an electrical harness 20 integrating the functions of electromagnetic protection and electric-arc detection. According to one embodiment, the strands 34 in the form of segments of optical fiber 36.1 are regularly distributed around the electrical connection 22.

According to a first embodiment that can be seen in FIGS. 4 and 5, the tubular jacket 30 comprises four strands 34, each in the form of a segment of optical fiber 36.1, regularly distributed around the electrical connection 22 in four bundles 30.1′. Thus, one bundle 30.1′ out of four comprises a strand 34 in the form of a segment of optical fiber 36.1. According to this first embodiment, each segment of optical fiber 36.1 ensures the detection of electric arcs over an angular sector of the order of 90°.

According to a second embodiment that can be seen in FIG. 6, the tubular jacket 30 comprises eight strands 34, each in the form of a segment of optical fiber 36.1, regularly distributed around the electrical connection 22 in eight bundles 30.1. According to a first arrangement, one bundle 30.1′ out of two comprises a strand 34 in the form of a segment of optical fiber 36.1. According to a second arrangement that can be seen in FIG. 6, the tubular jacket 30 comprises a plurality of pairs of adjacent bundles 30.1′ separated by two bundles 30.1 exclusively comprising metal strands 32. For each pair of adjacent bundles 30.1′, the first and second end strands, the ones that are furthest apart, are each in the form of a segment of optical fiber 36.1, the other strands 32 of each pair of adjacent bundles 30.1′ being made of metal. According to these two arrangements, the strands 34 in the form of segments of optical fiber 36.1 are regularly distributed around the electrical connection 22, each segment of optical fiber 36.1 ensuring the detection of electric arcs over an angular sector of the order of 45°.

According to the first and second embodiments, half or less of the bundles 30.1, 30.1′ each comprise at most one strand 34 in the form of a segment of optical fiber.

The strands 34 in the form of segments of optical fiber 36.1 have a diameter that is substantially identical to that of the metal strands 32, of the order of 150 to 250 μm.

According to one configuration, each optical fiber is a standard multi-mode optical fiber, for example of diameter 50/125 or 62.5/125. According to another configuration, each optical fiber is a single-mode optical fiber, for example of diameter 9/125. Of course, the invention is not limited to these optical fiber diameters, and a multi-mode or single-mode optical fiber of different diameter could be used.

According to one embodiment, the optical fibers 36.1 are polymer optical fibers (POFs) and/or polymer-clad fibers (PCFs). Regardless of the embodiment, the optical fibers 36.1 are configured to operate at temperatures of the order of 150 to 180° C. and have mechanical characteristics which allow braiding or overbraiding.

According to one embodiment that can be seen in FIGS. 3 and 4, the segments of optical fiber 36.1 are connected in parallel.

When the segments of optical fiber 36.1 are connected in parallel, the segments of optical fiber 36.1 are connected by at least one ferrule 38 to each end of the tubular jacket 30. By way of example, each ferrule 38 is used as a male contact intended to be inserted into a male connector and has a size 8.

Each strand 34 in the form of a segment of optical fiber 36.1 extends over the entire length of the tubular jacket 30, like the metal strands 32, and has at least one excess length at at least one end of the tubular jacket 30. Thus, each ferrule 38 is spaced apart from the end of the tubular jacket 30. This configuration makes it possible to simplify the connection of the segments of optical fiber to each other. According to one embodiment, each strand 34 in the form of a segment of optical fiber 36.1 has an excess length at each end of the tubular jacket 30.

The photo-detection component 36.2 and the control unit 36.3 of the system 36 for detecting electric arcs are not described further since they may be identical to those of the prior art.

According to one mode of operation, the tubular jacket 30 is obtained by simultaneously overbraiding, on the electrical connection 22, metal strands 32 forming at least part of the electromagnetic protection system 24 and strands 34 in the form of segments of optical fiber 36.1 forming at least part of the system 36 for detecting electric arcs so as to obtain a single tubular jacket 30 surrounding the electrical connection 22.

By way of example, the overbraiding process comprises:
a step of winding metal strands 32 and strands 34 in the form of segments of optical fiber 36.1 around reels,
a step of placing the reels on an overbraiding machine,
a step of adjusting the tension springs of the overbraiding machine,
a step of adjusting the braiding angle,
a step of braiding the tubular jacket 30 around the electrical connection 22.

This solution makes it possible to guarantee that the tubular jacket 30 is in contact with the electrical connection 22 and has a diameter, and therefore a mass, which is as small as possible. Furthermore, this solution makes it possible to obtain, at the end of the overbraiding process, a single tubular jacket 30 integrating the electromagnetic protection system 24 and the system 36 for detecting electric arcs.

According to one embodiment, the electrical harness 20 may comprise a protective sheath inserted between the tubular jacket 30 and the electrical connection 22, for example made of polytetrafluoroethylene (PTFE), in order to protect the electrical connection 22 during the overbraiding and/or a mechanical protection 40 added to the tubular jacket 30 in the form of a sheath obtained by overbraiding synthetic fibers, made of aramid, for example.

While at least one exemplary embodiment of the present invention(s) is disclosed herein, it should be understood that modifications, substitutions and alternatives may be apparent to one of ordinary skill in the art and can be made without departing from the scope of this disclosure. This disclosure is intended to cover any adaptations or variations of the exemplary embodiment(s). In addition, in this disclosure, the terms “comprise” or “comprising” do not exclude other elements or steps, the terms “a” or “one” do not exclude a plural number, and the term “or” means either or both. Furthermore, characteristics or steps which have been described may also be used in combination with other characteristics or steps and in any order unless the disclosure or context suggests otherwise. This disclosure hereby incorporates by reference the complete disclosure of any patent or application from which it claims benefit or priority.

1. An electrical harness comprising:
at least one electrical connection,
an electromagnetic protection system comprising a tubular jacket obtained by braiding bundles of strands and positioned around the electrical connection, at least 80% of the strands of the bundles being made of metal,
a system configured to detect electric arcs which comprises at least one optical fiber positioned close to the electrical connection and at least one photo-detection component configured to receive a light beam guided by the at least one optical fiber,
the tubular jacket comprising strands formed as segments of optical fiber forming at least part of the system configured to detect electric arcs, and wherein the strands formed as segments of optical fiber have a diameter that is substantially identical to that of the metal strands.

2. The electrical harness as claimed in claim 1, wherein all the strands are made of metal for at least half of the bundles of the tubular jacket while at least 75% of the strands are made of metal for a remainder of the bundles of the tubular jacket.

3. The electrical harness as claimed in claim 2, wherein the tubular jacket comprises sixteen bundles and four strands, each formed as a segment of optical fiber, regularly distributed around the electrical connection in four bundles.

4. The electrical harness as claimed in claim 2, wherein the tubular jacket comprises sixteen bundles and eight strands, each strand formed as a segment of optical fiber, regularly distributed around the electrical connection in eight of the bundles.

5. The electrical harness as claimed in claim 1, wherein each optical fiber is a single-mode or multi-mode optical fiber.

6. The electrical harness as claimed in claim 1, wherein the segments of optical fiber are connected in parallel.

7. The electrical harness as claimed in claim 1, wherein each strand formed as a segment of optical fiber extends over an entire length of the tubular jacket and has at least one excess length at at least one end of the tubular jacket.

8. A process for manufacturing an electrical harness as claimed in claim 1, wherein the tubular jacket is obtained by simultaneously overbraiding, on the electrical connection, metal strands forming at least part of the electromagnetic protection system and strands formed as segments of optical fiber forming at least part of the system for detecting electric arcs.

9. An aircraft comprising at least one electrical harness as claimed in claim 1.
